(19) United States
(12) Patent Application Publication
(10) Pub. No.: US 2026/0129785 A1
(43) Pub. Date: May 7, 2026

(54) ZERO U UNIVERSAL MAGNETIC CABLE MANAGEMENT SYSTEM

(71) Applicant: David S. May, Claymont, DE (US)

(72) Inventor: David S. May, Claymont, DE (US)

(21) Appl. No.: 18/968,079

(22) Filed: Dec. 4, 2024

Related U.S. Application Data
(60) Provisional application No. 63/606,811, filed on Dec. 6, 2023.

(51) Int. Cl. H05K 7/14

(52) U.S. Cl. CPC H05K 7/1491

(57) ABSTRACT

The disclosed methods, devices and systems provide for a universal cable management system device having one or more, or a plurality of magnets placed on the rear of the device for attaching to a metal server cabinet.

### CROSS REFERENCE TO RELATED APPLICATIONS

This application claims the benefit of priority under 37 CFR § 119(e) to U.S. Provisional Patent Application No. 63/606,811 filed on Dec. 6, 2023, titled “ZERO U UNIVERSAL MAGNETIC CABLE MANAGEMENT SYSTEM,” the contents of which are hereby incorporated by reference in its entirety for all purposes.

### TECHNICAL FIELD OF THE INVENTION

The present disclosure generally relates to cable management systems, and more particularly, to methods, devices, and systems for a zero u universal magnetic cable management system.

### BACKGROUND OF THE INVENTION

Cable management refers to the management of electrical or optical cables in a server cabinet or an installation. Without a management system, cables can easily become tangled, making them difficult to work with, sometimes resulting in devices accidentally becoming unplugged as one attempts to move a cable. Such cases are known as “cable spaghetti,” and any kind of problem diagnosis and future updates to such enclosures could be very difficult. Cable management both supports and contains cables during their installation and makes subsequent maintenance or changes to the cable system easier. A cable management systems is a crucial tool for managing cables connecting between racks and enclosures housing servers, switches and patch panels. Most cables are notorious for falling into disarray, whereas components need straightforward organization keeping them fully accessible when needed for optimal management.

### SUMMARY OF THE INVENTION

The disclosed methods, devices and systems provide for a universal cable management system device having one or more, or a plurality of magnets placed on the rear of the device for attaching to a metal server cabinet. The magnets can be of any shape or size and with sufficient strength to allow for manually attaching and removing the device to a server cabinet while supporting and securing a plurality of IT cables.

### BRIEF DESCRIPTION OF THE DRAWINGS

The disclosure, in accordance with one or more various embodiments, is described in detail with reference to the following figures. The drawings are provided for purpose of illustration only and merely depict exemplary embodiments of the disclosure. These drawings are provided to facilitate the reader's understanding of the disclosure and should not be considered limiting of the breadth, scope, or applicability of the disclosure. It should be noted that for clarity and ease of illustration these drawings are not necessarily made to scale.

FIG. 1 illustrates an embodiment of a front view of a standard cable management system device;

FIG. 2 illustrates an embodiment of a front view of a standard cable management system device attached to a rack unit space in a server cabinet;

FIG. 3 illustrates an embodiment of a rear view of universal cable management system device;

FIG. 4 illustrates an embodiment of a front view of a universal cable management system device equipped with a brush strips arrangement;

FIG. 5 illustrates an embodiment of a front view of the universal cable management system device attached on the top of a server cabinet;

FIG. 6 illustrates an embodiment of a front view of the universal cable management system device attached to a unit space in a server cabinet;

FIG. 7 illustrates an embodiment of a side view of the universal cable management system device horizontally attached to an inside wall of a server cabinet; and

FIG. 8 illustrates an embodiment of a side view of the universal cable management system attached to the back panel or rear of a server cabinet.

### DETAILED DESCRIPTION OF EXEMPLARY EMBODIMENTS

The following description is presented to enable a person of ordinary skill in the art to make and use embodiments described herein. Descriptions of specific devices, techniques, and applications are provided only as examples. Various modifications to the examples described herein will be readily apparent to those of ordinary skill in the art, and the general principles defined herein may be applied to other examples and applications without departing from the spirit and scope of the disclosure. Thus, the disclosure is not intended to be limited to the examples described herein and shown but is to be accorded the scope consistent with the claims.

Information Technology (IT) production equipment includes the servers, storage, network switches, routers, telecommunications hardware and other devices that fulfill the primary purpose of the IT installation. Racks or server cabinets organize IT equipment into standardized assemblies that make efficient use of space and other resources. A rack or server cabinet consists of two or four vertical mounting rails and the supporting framework required to keep the rails in place. The rails and framework are typically made of steel or aluminum to support hundreds or even thousands of pounds of equipment.

The width of the rails, the horizontal and vertical spacing of the mounting holes, the size of the equipment cabinets and other measurements are standardized. This ensures that standard IT equipment will always be compatible with standard racks. Most IT equipment is nominally 19 inches wide (including mounting hardware) and follows a standard set by the Electronics Industry Alliance (EIA) and now maintained by the Electronic Components Industry Association (ECIA).

Although 19-inch racks are always the same nominal width, the depth and height can vary. The depth of the rack rails is usually adjustable to some degree. The height of the rack is divided into standardized segments called rack units. Each rack unit is 1.75 inches high, and the height of a rack or an equipment cabinet is expressed as the number of rack units followed by the letter “U”. For example, a 42U rack contains 42 rack units. That does not mean the rack is exactly 42×1.75 inches high because racks usually include at least a little extra space at the top and bottom that isn't usable rack space. It does mean that the rack will accommodate any combination of standard rack equipment up to 42U—whether it's 42×1U switches, 14×3U servers or 21×1U switches with 7×3U servers.

There are three primary types of racks: open frame racks, rack enclosures and wall-mount racks. Open frame racks have frames with mounting rails, but without sides or doors. Rack enclosures or rack cabinets have removable front and rear doors, removable side panels and four adjustable vertical mounting rails (posts). Wall-mount racks are designed to be attached to the wall, saving floor space and fitting in areas where other racks can't. They can be made of an open frame rack or enclosed cabinets.

Racks are designed to hold all standard 19-inch rack-mountable equipment, as long as it isn't too deep for the cabinet or too high to fit in the available rack spaces. The equipment often includes removable mounting brackets or “ears” that fasten to the vertical rack rails with screws. Heavier equipment may also include horizontal rails or shelves that mount in the rack to provide extra support.

Racks also accommodate IT infrastructure and rack accessories that support the operation of the production equipment. This includes equipment like UPS systems (uninterruptible power supplies), PDUs, cable managers, KVM switches, patch panels and shelves. Although most equipment is designed to fit in standard rack spaces, vertical PDUs and cable managers mount to vertical rails without using any rack spaces. Equipment that is installed this way is referred to as 0U (“zero U”).

A rack's rails can have square or round holes, which allow mounting rack equipment to servers with screws or bolts. On some racks, keyhole slots are included on to allow installation of compatible vertical power distribution units (PDUs) and cable managers without fumbling with screws and mounting brackets. However, all of these types of racks are limited in being positioned where the screws, bolts, or keyholes are located on a server.

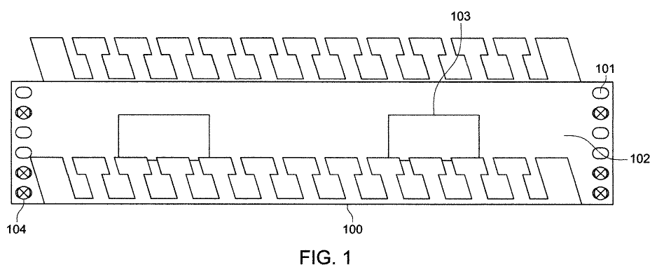

FIG. 1 illustrates an embodiment of a front view of a standard cable management system device 100. This device includes a series of openings 101 on each side for securing the device to a server (not shown). The device also includes one or more openings 102 that allow a plurality of cables (not shown) to enter past one or more server cable dividing tabs or openings 103 thereby organizing the cables into a manageable system. A series of screws or bolts 104 can secure the device through the openings 101 to attach it securely to a cabinet, e.g., a metal server cabinet (not shown). This type of device can be a hassle to install and move as it takes time to set up with each move. In addition, this device is limited to where the corresponding openings 102 are located on the cabinet for placement of the plurality of cables, which may not be the most convenient place for the cables.

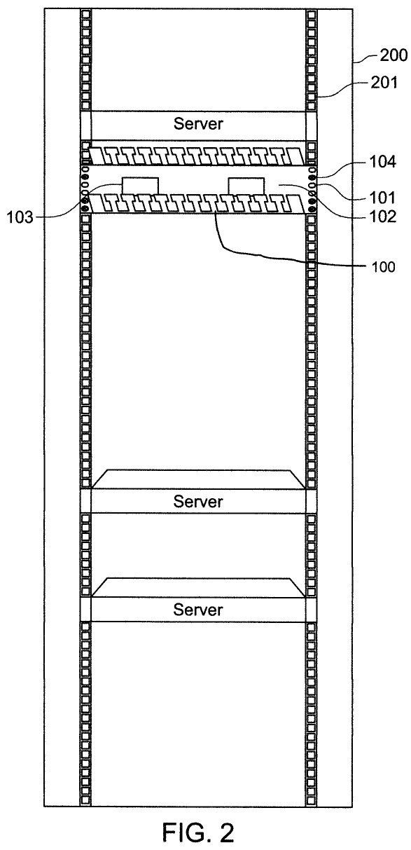

FIG. 2 illustrates an embodiment of a front view of a standard cable management system device 100 attached to a rack unit space in a server cabinet 200. As shown in this figure, the server cabinet can include a server cabinet bracket 201, which can support one or more servers that can be held in place by a series of cabinet bolts (not shown). In addition, the device shown can be secured to the cabinet through a series of screws or bolts 104, wherein the openings 101 on the device correspond to the openings on the server cabinet.

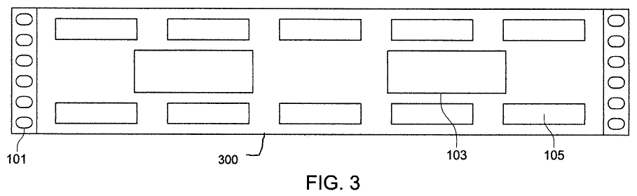

FIG. 3 illustrates an embodiment of a rear view of universal cable management system device 300. As shown in this figure, the device includes one or more, or a plurality of magnets 105, which can be placed on the rear of the device for attaching to a metal server cabinet (not shown). The magnets can be of any number and any convenient size, shape and strength.

In an embodiment, the magnets may include a refrigerator type magnet. Unlike most conventional magnets that have distinct north and south poles, flexible refrigerator type magnets are magnetized during manufacture in a sophisticated magnetization pattern called a Hallbach array. This construction nearly doubles the magnetic field on the refrigerator side and provides almost zero magnetic field on the other. Most server cabinets are constructed with steel framing and the magnetic field lines pass through the framing metal from the north pole to the south pole allowing magnets to stick to the server frame. In addition, there are several options available for attaching the magnets to the device. For surfaces such as metal, typical strong adhesives such as two-part epoxies, Loctite, Liquid Nails, Super Glue, Gorilla Glue, and the like all work well.

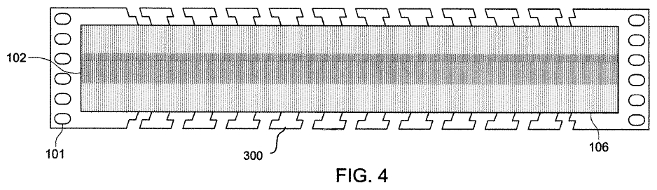

FIG. 4 illustrates an embodiment of a front view of a universal cable management system device 300 equipped with a brush strips arrangement 106. The brush strips can be made of high density nylon brush, which can protect and organize cables while keeping dust and dirt out.

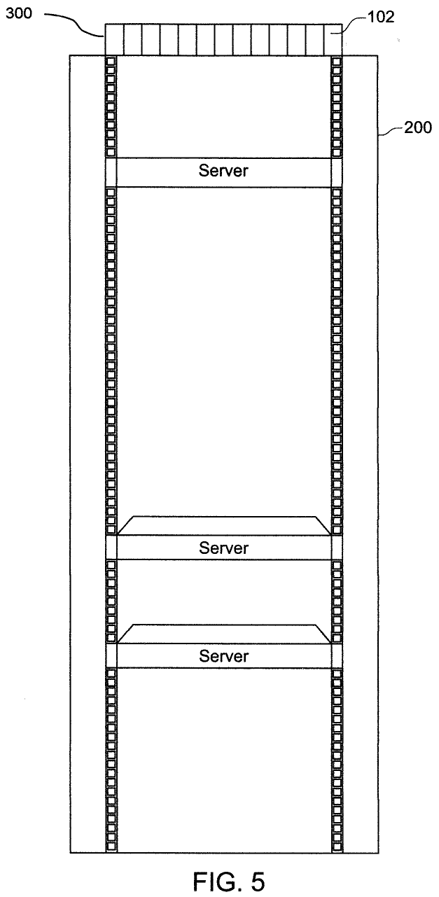

FIG. 5 illustrates an embodiment of a front view of the universal cable management system device 300 attached on the top of a server cabinet 200. As shown in this figure, the device can be magnetically attached to the top of the server cabinet through one or more magnets 105 (not shown). The device can be easily manually located and secured to different and more convenient workplaces on the server cabinet.

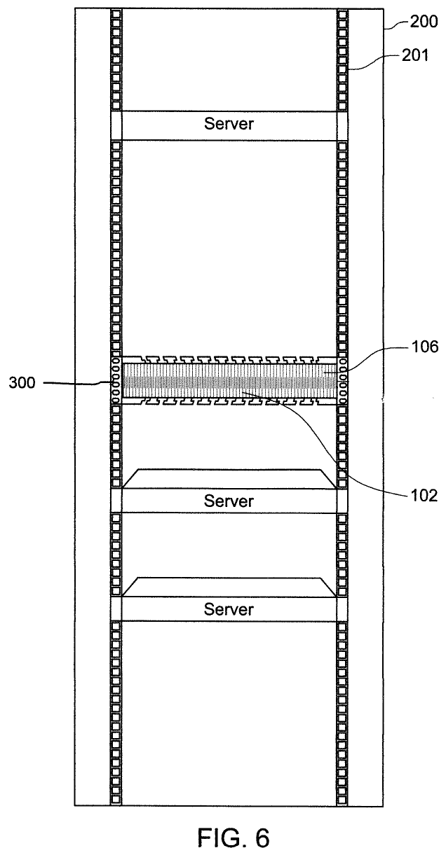

FIG. 6 illustrates an embodiment of a front view of the universal cable management system device 300 attached to a rack unit space in a server cabinet 200. As shown in this figure, the server cabinet can include a plurality of openings for securing a cable management device through screws or bolts. In an embodiment, the device can be attached directly to the server cabinet through the magnet system described herein.

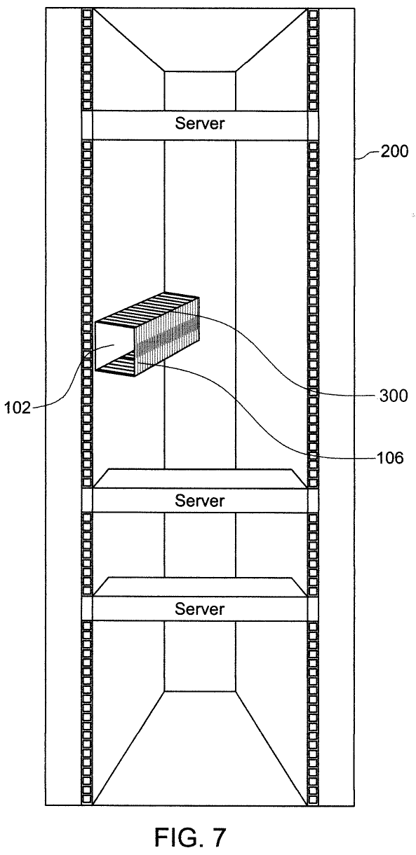

FIG. 7 illustrates an embodiment of a side view of the universal cable management system device 300 horizontally attached to an inside wall of a server cabinet 200. The device can be attached to the wall of the cabinet through the magnet system described herein and therefore, is not limited to the location of the preset openings in the server cabinet.

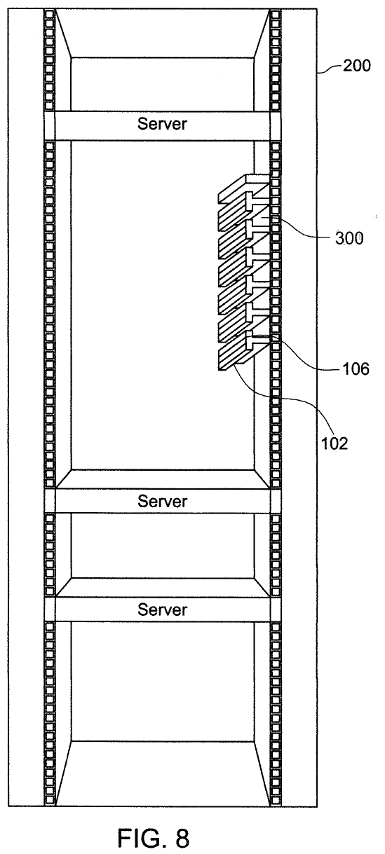

FIG. 8 illustrates an embodiment of a side view of the universal cable management system device 300 attached to the back panel or rear of a server cabinet 200. The device is attached to a rear wall of the server cabinet through the magnet system described herein and therefore, is not limited to the location of the preset openings in the server cabinet.

While the inventive features have been particularly shown and described with reference to preferred embodiments thereof, it will be understood by those in the art that the foregoing and other changes can be made therein without departing from the sprit and the scope of the disclosure. Likewise, the various diagrams may depict an example architectural or other configuration for the disclosure, which is done to aid in understanding the features and functionality that can be included in the disclosure. The disclosure is not restricted to the illustrated example architectures or configurations but can be implemented using a variety of alternative architectures and configurations. Additionally, although the disclosure is described above in terms of various exemplary embodiments and implementations, it should be understood that the various features and functionality described in one or more of the individual embodiments are not limited in their applicability to the particular embodiment with which they are described. They instead can be applied alone or in some combination, to one or more of the other embodiments of the disclosure, whether or not such embodiments are described, and whether or not such features are presented as being a part of a described embodiment. Thus, the breadth and scope of the disclosure should not be limited by any of the above-described exemplary embodiments.

What is claimed is:

1. A universal cable management system device, comprising:
a management device having one or more openings for organizing cables; and
one or more magnets attached to a rear of the management device, wherein the one or more magnets can be of any shape or size and with sufficient strength to allow for manually attaching and removing the device to a server cabinet while supporting and securing a plurality of IT cables.

2. The universal cable management system device of claim 1, wherein the one more magnets are refrigerator type magnets.

3. The universal cable management system device of claim 2, wherein the one or more refrigerator type magnets are attached to the universal cable management system device with a strong adhesive selected from two-part epoxies, Loctite, Liquid Nails, Super Glue, Gorilla Glue, and the like.

4. The universal cable management system device of claim 1, further comprising a brush strip arrangement.

5. The universal cable management system device of claim 4, wherein the brush strip arrangement is composed of a high density nylon brush, which can protect and organize cables while keeping dust and dirt out.

6. The universal cable management system device of claim 1, wherein the device is magnetically attached to a front panel, a back or real panel, or a side panel of the server cabinet.
